(19) United States
(12) Patent Application Publication
(10) Pub. No.: US 2019/0035659 A1
(43) Pub. Date: Jan. 31, 2019

(54) AIR PURIFYING DEVICE FOR FRONT OPENING UNIFIED POD CAPABLE OF PREVENTING AIR LEAKAGE AND AIR PURIFYING SYSTEM

(71) Applicant: FOXSEMICON INTEGRATED TECHNOLOGY, INC., Miao-Li Hsien (TW)

(72) Inventors: YI-CHUN CHIU, Miaoli Hsien (TW); CHUN-KAI HUANG, Miaoli Hsien (TW); CHIH-CHENG LU, Miaoli Hsien (TW); CHUN-CHUNG CHEN, Miaoli Hsien (TW)

(21) Appl. No.: 15/826,619

(22) Filed: Nov. 29, 2017

(30) Foreign Application Priority Data
Jul. 31, 2017 (CN) 201710640888.9

(51) Int. Cl. H01L 21/673

(52) U.S. Cl. CPC H01L 21/67389

(57) ABSTRACT

An air purifying device for an FOUP includes an air supply assembly. The air supply assembly includes an air supply tube and an airtight connecting unit connecting the tube to the FOUP in an airtight manner. The air tight connecting unit includes an elastic absorbing portion, a nozzle, and a driver. An initial position of the elastic absorbing portion is lower than a supporting surface of a load port before the FOUP is placed on the supporting surface. One end of the nozzle is fixedly inserted to the elastic absorbing portion, and another end of the nozzle is movably inserted to the air supply tube. The driver can drive the nozzle and the elastic absorbing portion to move upward to press against the FOUP when the FOUP is placed on the supporting surface, causing the elastic absorbing portion to be vertically deformed to maintain an airtight connection.

### FIELD

The subject matter herein generally relates to silicon wafer manufacturing, and particularly to an air purifying device for a front opening unified pod (FOUP) and an air purifying system.

### BACKGROUND

FOUPs are plastic enclosures designed to securely and safely hold silicon wafers in a controlled environment, and to allow the silicon wafers to be transferred between machines for processing.

With the manufacture processes for semiconductors becoming shorter, the queue time between two successive procedures also becomes shorter. Thus, silicon wafers waiting for a time period longer than the queue time may lose efficacy. Thus, it may be desirable to increase the queue time between two successive procedures. To maintain quality of the silicon wafers to adapt for the increased queue time, an air purifying device is needed to purify air in the FOUP to remove moisture and oxygen, thereby avoiding contamination and/or damage to the silicon wafers.

When in operation, the air purifying device is placed under a load port. When the FOUP is placed on the load port, at least one groove at the bottom of the FOUP can match at least one guiding pin on the top of the load port to correct any horizontal displacement of the FOUP, thereby allowing the FOUP to be precisely positioned on the load port. However, since the FOUP may touch an elastic nozzle of the air purifying device during the displacement correction process, the elastic nozzle can experience horizontally deformation, which may exert a horizontal shear force to the FOUP. The shear force can cause the FOUP to slide and the silicon wafers in the FOUP to collide with one another. Furthermore, the shear force also can cause air leakage.

### BRIEF DESCRIPTION OF THE DRAWINGS

Implementations of the present disclosure will now be described, by way of example only, with reference to the attached figures.

FIG. 1 is a block diagram of an exemplary embodiment of an air purifying system including an air purifying device.

FIG. 2 is a diagrammatic view of an airtight connecting unit of the air purifying device of FIG. 1.

FIG. 3 is diagrammatic view showing the the air purifying device of FIG. 1 placed under a load port before a FOUP is placed on the load port.

FIG. 4 is diagrammatic view showing the the air purifying device of FIG. 1 placed under a load port when a FOUP is placed on the load port.

FIG. 5 is similar to FIG. 4, but showing the airtight connecting unit abutting against the bottom of the FOUP.

FIG. 6 is a diagram showing relative humidities of FOUP, using the air purifying device of FIG. 1, with different air flow rates.

FIG. 7 is a diagram showing relative humidities of FOUP, using the air purifying device of FIG. 1, with different air pressures.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

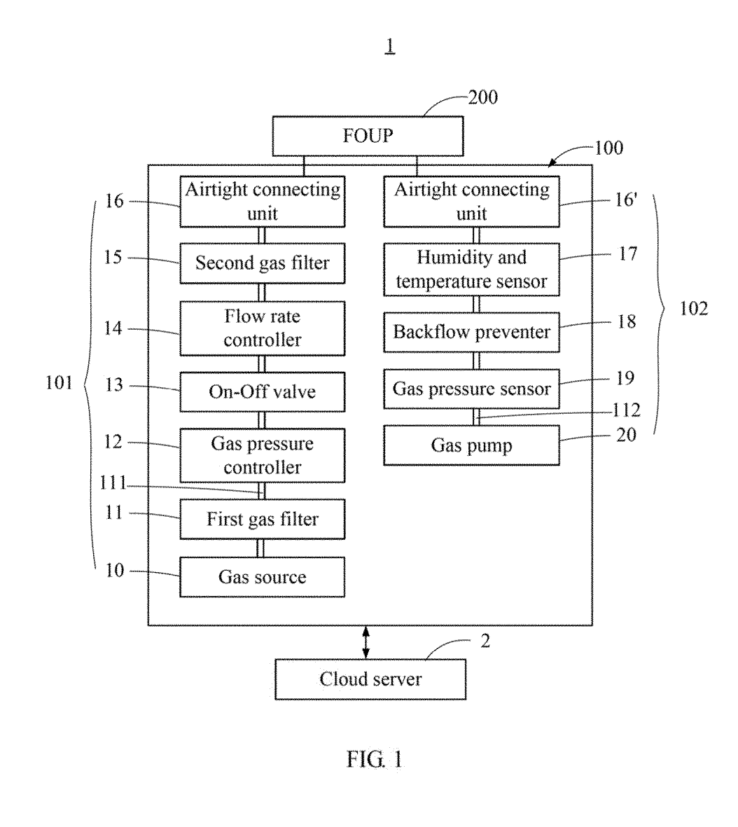

FIG. 1 illustrates an exemplary embodiment of an air purifying system 1 comprising an air purifying device 100 and a FOUP 200 connected to the air purifying device 100.

The air purifying device 100 comprises an air supply assembly 101 and an air discharging assembly 102. When the air supply assembly 101 receives a trigger signal, the air supply assembly 101 supplies purified air to the FOUP 200, the purified air meets requirements of humidity and air pressure. The air discharging assembly 102 discharges air from the FOUP 200 when the air supply assembly 101 begins to supply the purified air to the FOUP 200, and detects a humidity and a temperature of the discharged air. The detected humidity and the detected temperature correspond to a relative humidity of the discharged air.

In at least one exemplary embodiment, the air purifying device 100 can communicate with a cloud server 2 in a wired or a wireless manner. The cloud server 2 sends the trigger signal to the air supply assembly 101 and the air discharging assembly 102, to inform the air supply assembly 101 to begin to supply purified air to the FOUP 200, and the air discharging assembly 102 to begin to discharge air from the FOUP 200. The air purifying device 100 further sends the detected humidity and the detected temperature of the discharged air to the cloud server 2. Thus, an authorized user of the cloud server 2 can calculate the relative humidity of the discharged air according to the detected humidity and the detected temperature, and compare the calculated relative humidity with a preset relative humidity. When the calculated relative humidity is equal to the preset relative humidity, the cloud server 2 sends a stop signal to the air supply assembly 101 and the air discharging assembly 102. The stop signal informs the air supply assembly 101 to stop supplying the purified air to the FOUP 200, and the air discharging assembly 102 to stop discharging air from the FOUP 200. That is, the air purifying device 100 stops working.

In other exemplary embodiment, the air supply assembly 101 can communicate with the air discharging assembly 102 in a wired or a wireless manner. The air discharging assembly 102 calculates the relative humidity of the discharged air and compares the calculated relative humidity with the preset relative humidity. When the calculated relative humidity is equal to the preset relative humidity, the air discharging assembly 102 stops discharging air from the FOUP 200. The air discharging assembly 102 further sends a stop signal to the air supply assembly 101, thereby informing the air supply assembly 101 to stop supplying the purified air to the FOUP 200.

The purified air can include, but is not limited to, compressed dry air (CDA) and/or nitrogen (N₂).

The air supply assembly 101 comprises an air source 10. The air supply assembly 101 can process air from the air source 10 to obtain the purified air and supply the purified air to the FOUP 200. In at least one exemplary embodiment, the air supply assembly 101 further comprises a first air filter 11, an air pressure controller 12, an On-Off valve 13, a flow rate controller 14, a second air filter 15, an airtight connecting unit 16, and an air supply tube 111. The air supply tube 111 connects the first air filter 11, the air pressure controller 12, the On-Off valve 13, the flow rate controller 14, the second air filter 15, and the airtight connecting unit 16. The air supply assembly 101 is connected to the air source 10 through the first air filter 11, and further connected to the FOUP 200 through the airtight connecting unit 16. The air pressure controller 12, the On-Off valve 13, the flow rate controller 14, and the second air filter 15 are arranged between the first air filter 11 and the airtight connecting unit 16 in that order. In other exemplary embodiments, the order of connection of the air pressure controller 12, the On-Off valve 13, the flow rate controller 14, and the second air filter 15 may vary.

The first air filter 11 filters the air from the air source 10 to remove fine particles (for example, dust) in the air.

The air pressure controller 12 senses an air pressure of the air from the first air filter 11, and compares the sensed air pressure to a preset air pressure range. If the sensed air pressure is outside the preset air pressure range, the air pressure controller 12 adjusts the air pressure of the air until the sensed air pressure falls within the preset air pressure range. In at least one exemplary embodiment, the air pressure controller 12 comprises an air pressure sensor and an air pressure valve. The preset air pressure range is about −1 kpa to about −6 kpa.

The On-Off valve 13 can be switched between an On-state and an Off-state. When the On-Off valve 13 is in the On-state, the On-Off valve 13 can allow the air from the air pressure controller 12 to pass through. When the On-Off valve 13 is in the Off-state, the On-Off valve 13 prevents the air from passing through. That is, the On-Off valve 13 can control the air supply assembly 101 to stop supplying air to the FOUP 200.

The flow rate controller 14 senses a flow rate of the air from the On-Off valve 13, and compares the sensed flow rate with a preset flow rate range. When the sensed flow rate is outside the preset flow rate range, the flow rate controller 14 adjusts the flow rate of the air until the sensed flow rate falls within the preset flow rate range. The preset flow rate range can be less than 200 L/min. In at least one exemplary embodiment, when the FOUP 200 is closed, the flow rate controller 14 adjusts the flow rate of the air until the sensed flow rate falls within a first range belonging to the preset flow rate range. When the FOUP 200 is opened to allow the silicon wafers to be transferred, the flow rate controller 14 adjusts the flow rate of the air until the sensed flow rate falls within a second range belonging to the preset flow rate range that is greater than the first range, thereby preventing the air from the ambient environment from entering the FOUP 200 due to air pressure imbalance. For example, the first range is less than about 100 L/min, and the second range is about 100 L/min to about 200 L/min.

The second air filter 15 filters the air from the flow rate controller 14, thereby removing fine particles in the air generated by the first air filter 11, the air pressure controller 12, the On-Off valve 13, and the flow rate controller 14, to obtain the purified air.

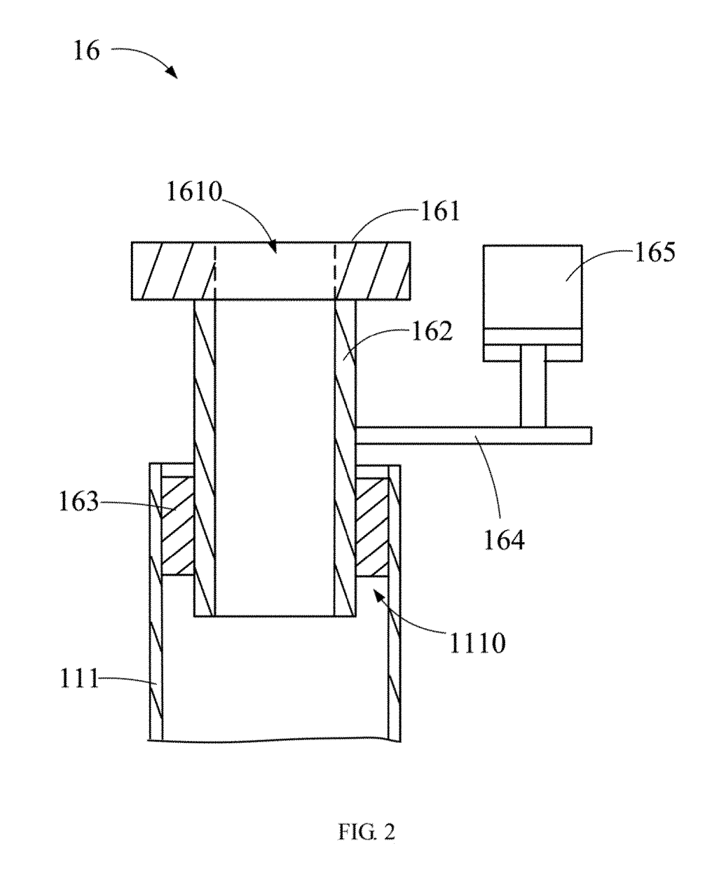

Referring to FIG. 2, the airtight connecting unit 16 connects the second air filter 15 to the FOUP 200 in an airtight manner, thereby avoiding any air leakage when the purified air is supplied to the FOUP 200. In at least one exemplary embodiment, the airtight connecting unit 16 comprises an elastic absorbing portion 161, a nozzle 162, a sleeve 163, a connecting rod 164, and a driver 165. The elastic absorbing portion 161 is made of an elastic material (e.g., rubber) which can be deformed when pressed. One end of the nozzle 162 is fixedly inserted to the elastic absorbing portion 161, thereby forming an opening 1610 in the elastic absorbing portion 161. Another end (e.g., an opposite end) of the nozzle 162 is movably inserted to the air supply tube 111. Thus, the purified air can be supplied to the FOUP 200 through the nozzle 162 and the opening 1610. The sleeve 163 wraps the nozzle 162, and seals a gap 1110 between the air supply tube 111 and the nozzle 162 to prevent air leakage through the gap 1110. The connecting rod 164 is connected to the nozzle 162. The driver 165 is connected to the connecting rod 164, and can vertically move the nozzle 162 and the elastic absorbing portion 161 through the connecting rod 164. In at least one exemplary embodiment, the driver 165 is an air cylinder having one end of the piston rod of the air cylinder is connected to the connecting rod 164.

In an exemplary embodiment, the air discharging assembly 102 comprises an airtight connecting unit 16′, a humidity and temperature sensor 17, a backflow preventer 18, an air pressure sensor 19, an air pump 20, and an air discharging tube 112 connecting the airtight connecting unit 16′, the humidity and temperature sensor 17, the backflow preventer 18, the air pressure sensor 19, and the air pump 20.

The air pump 20 generates negative air pressure which pulls the air in the FOUP 200 towards the air pump 20. In at least one exemplary embodiment, the air pump 20 is a vacuum air pump. The airtight connecting unit 16′, the humidity and temperature sensor 17, the backflow preventer 18, and the air pressure sensor 19 are arranged between the FOUP 200 and the air pump 20 in that order. In other exemplary embodiments, the order of connection of the airtight connecting unit 16′, the humidity and temperature sensor 17, the backflow preventer 18, and the air pressure sensor 19 may vary.

The airtight connecting unit 16′ connects the humidity and temperature sensor 17 to the FOUP 200 in an airtight manner, thereby avoiding any air leakage when the discharged air enters the humidity and temperature sensor 17. In at least one exemplary embodiment, the structure of the airtight connecting unit 16′ is substantially similar to that of the airtight connecting unit 16. That is, the airtight connecting unit 16′ also comprises an elastic absorbing portion 161, a nozzle 162, a sleeve 163, a connecting rod 164, and a driver 165, substantially similar to what's shown in FIG. 2.

The humidity and temperature sensor 17 detects the humidity and the temperature of the discharged air. In at least one exemplary embodiment, the humidity and temperature sensor 17 comprises a temperature-sensitive resistor and a humidity-sensitive resistor. When the relative humidity of the discharged air is equal to the preset relative humidity, the air source 10 is shut down, that is, the air supply assembly 101 stops supplying the purified air to the FOUP 200.

The air pressure sensor 19 senses an air pressure of the discharged air.

The backflow preventer 18 prevents backflow of the discharged air when the sensed air pressure is greater than a preset air pressure (for example, when the negative air pressure changes to positive air pressure). That is, the backflow preventer 18 can prevent air from the ambient environment from flowing back to the FOUP 200. In at least one exemplary embodiment, the backflow preventer 18 is a check valve.

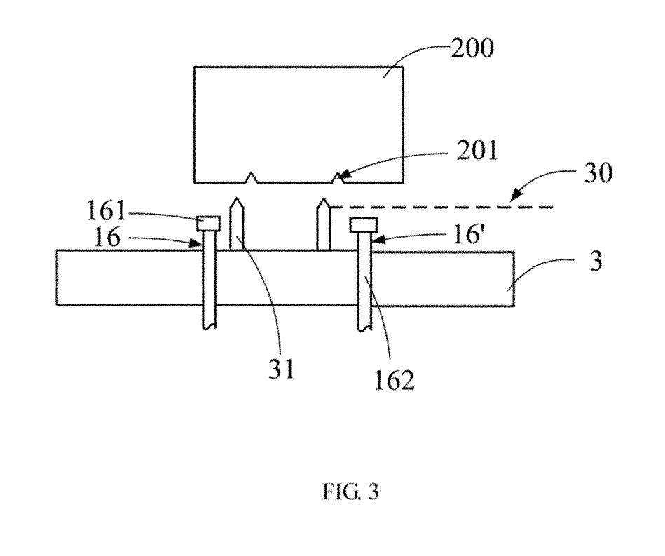

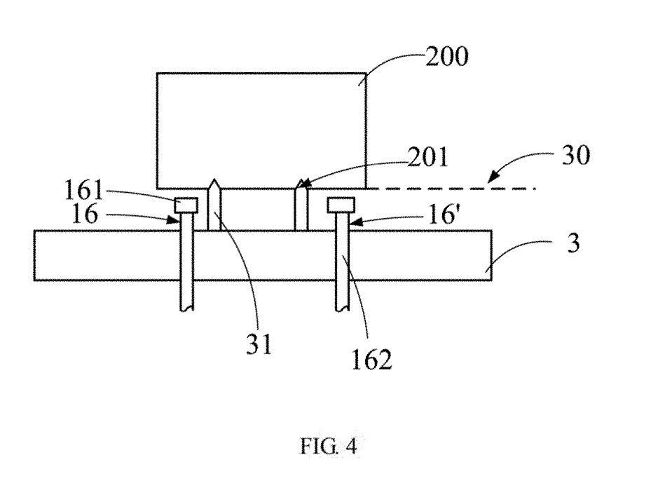

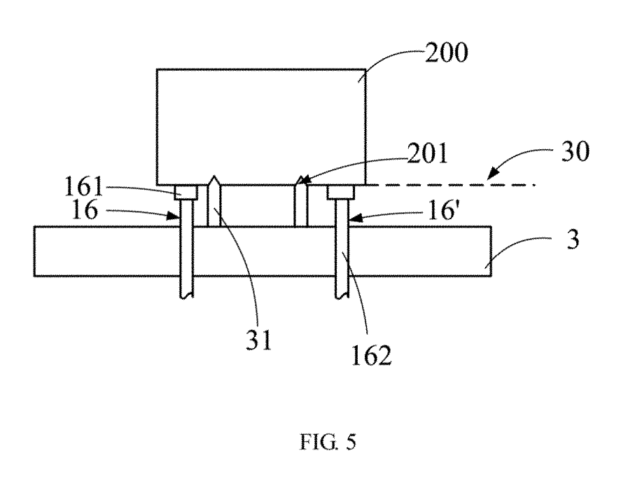

Referring to FIGS. 3-5, in operation, the air purifying device 100 is placed under a load port 3 (FIGS. 3-5 only show the airtight connecting units 16, 16′ of the air purifying device 100 for simplicity). An overhead hoist transport (not shown) is used to place the FOUP 200 on a supporting surface 30 above the load port 3. Before the FOUP 200 is placed on the supporting surface 30 of the load port 3, an initial position of the elastic absorbing portion 161 is lower than the supporting surface 30 (as shown in FIG. 3). When the FOUP 200 is placed on the load port 3, the grooves 201 at the bottom of the FOUP 200 match the guiding pins 31 on the top of the load port 3 to correct any horizontal displacement of the FOUP 200, thereby supporting the FOUP 200 at the supporting surface 30 and allowing the FOUP 200 to be precisely positioned on the load port 3. At this time, since the initial position of the elastic absorbing portion 161 is lower than the supporting surface 30, the elastic absorbing portion 161 is spaced away from the bottom of the FOUP 200 (as shown in FIG. 4). Then, the driver 165 can drive the elastic absorbing portion 161 to move upward to abut against the bottom of the FOUP 200. Thus, the elastic absorbing portion 161 presses against the bottom of the FOUP 200 (as shown in FIG. 5). The elastic absorbing portion 161 can be vertically deformed when pressed, and maintain an airtight connection between the second air filter 15 and the FOUP 200.

Since the elastic absorbing portion 161 is spaced away from the bottom of the FOUP 200 when the FOUP 200 is placed on the load port 3, the elastic absorbing portion 161 applies no horizontal shear force at the bottom of the FOUP 200 during the displacement correction of the FOUP 200. That is, the elastic absorbing portion 161 does not apply a horizontal shear force to the FOUP 200 when the FOUP 200 is placed on the load port 3, thereby preventing the silicon wafers in the FOUP 200 from colliding with one another. Furthermore, since the elastic absorbing portion 161 does not apply a horizontal shear force to the FOUP 200, the elastic absorbing portion 161 is not horizontally deformed. Thus, air leakage can be avoided.

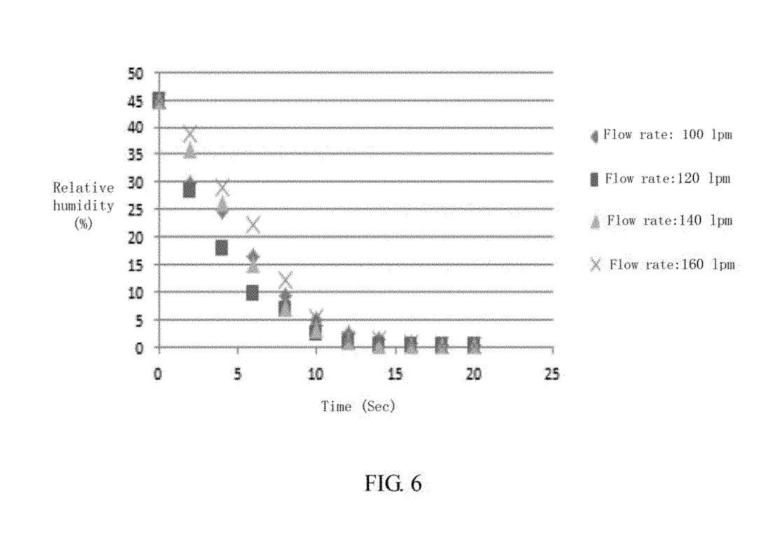

Referring to FIG. 6, an original relative humidity of the air in the FOUP 200 is about 45%. When the air pressure of the purified air is about −2 kpa and the flow rate of the purified air is equal to or greater than 100 L/min, the relative humidity of the air can be decreased to about 10% in 6 seconds.

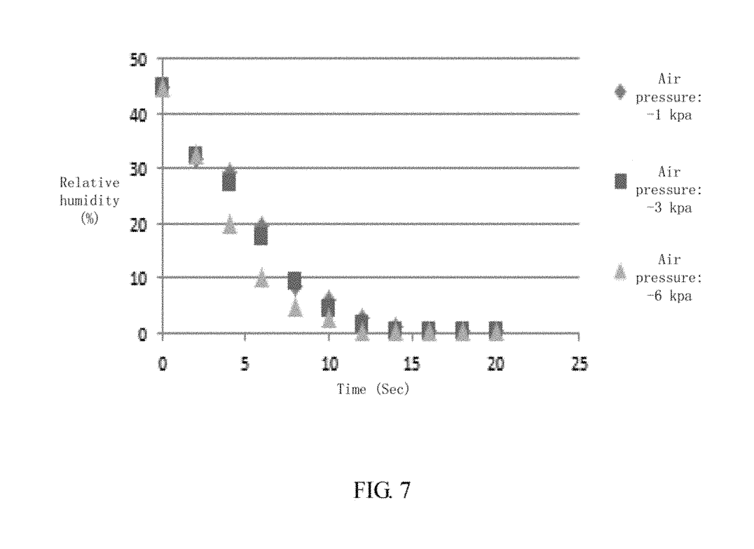

Referring to FIG. 7, an original relative humidity of the air in the FOUP 200 is about 45%. When the air pressure of the purified air is about −1 kpa to about −6 kpa and the flow rate of the purified air is equal to 130 L/min, the relative humidity of the air can also be decreased to about 10% in 6 seconds.

When the FOUP 200 is placed on the load port, an anemometer is positioned adjacent to the airtight connecting units 16, 16′. The anemometer can test that the flow rate of the air surrounding the airtight connecting units 16, 16′ is less than 1 meter/sec. That is, the airtight connecting units 16, 16′ can avoid air leakage when the FOUP 200 is placed on the load port.

With the above configuration, the air purifying device 100 can purify air of the FOUP 200 and instantly monitor the result of purification, thereby avoiding contamination and/or damage to the silicon wafers in the FOUP 200. Furthermore, the air purifying device 100 can prevent the FOUP 200 from moving when the FOUP 200 is placed on the load port 3, thereby preventing the silicon wafers in the FOUP 200 from colliding with one another. Finally, since the elastic absorbing portion 161 applies no horizontal shear force at the FOUP 200 when the FOUP 200 is placed on the load port 3, the elastic absorbing portion 161 is not horizontally deformed. Thus, air leakage can be avoided.

Even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments, to the full extent indicated by the plain meaning of the terms in which the appended claims are expressed.

What is claimed is:

1. An air purifying device for a front opening unified pod (FOUP), the air purifying device comprising:
an air supply assembly comprising:
an air source, the air supply assembly supplying purified air from the air source to the FOUP;
an air supply tube connected to the air source; and
an airtight connecting unit connecting the air supply tube to the FOUP in an airtight manner, the air tight connecting unit comprising:
an elastic absorbing portion made of an elastic material, an initial position of the elastic absorbing portion being lower than a supporting surface of a load port before the FOUP is placed on the supporting surface;
a nozzle, one end of the nozzle fixedly inserted to the elastic absorbing portion to form an opening in the elastic absorbing portion, another end of the nozzle movably inserted to the air supply tube; and
a driver connected to the nozzle, the driver configured to drive the nozzle and the elastic absorbing portion to move upward to press against a bottom of the FOUP when the FOUP is placed on the supporting surface, thereby causing the elastic absorbing portion to be vertically deformed to maintain an airtight connection.

2. The air purifying device of claim 1, wherein the air tight connecting unit further comprises a connecting rod connected to the nozzle, the driver is configured to drive the nozzle and the elastic absorbing portion to move upward through the connecting rod.

3. The air purifying device of claim 1, wherein the driver is an air cylinder.

4. The air purifying device of claim 1, further comprising:
an air discharging assembly, comprises:
an air pump, wherein the air discharging assembly discharges air from the FOUP by the air pump when the air supply assembly begins to supply the purified air to the FOUP, and detects a humidity and a temperature of the discharged air, the detected humidity and the detected temperature corresponding to a relative humidity of the discharged air, when the relative humidity is equal to a preset relative humidity, the air supply assembly stops supplying the purified air to the FOUP and the air discharging assembly stops discharging air from the FOUP;
an air discharging tube connected to the air pump; and
another the said airtight connecting unit connecting the air discharging tube to the FOUP in an airtight manner.

5. The air purifying device of claim 4, wherein the air pump is a vacuum air pump.

6. The air purifying device of claim 1, wherein the elastic absorbing portion is made of rubber.

7. An air purifying system comprising:
a front opening unified pod (FOUP); and
an air purifying device comprising:
an air supply assembly comprising:
an air source, the air supply assembly supplying purified air from the air source to the FOUP;
an air supply tube connected to the air source; and
an airtight connecting unit connecting the air supply tube to the FOUP in an airtight manner, the air tight connecting unit comprising:
an elastic absorbing portion made of an elastic material, an initial position of the elastic absorbing portion being lower than a supporting surface of a load port before the FOUP is placed on the supporting surface;
a nozzle, one end of the nozzle fixedly inserted to the elastic absorbing portion to form an opening in the elastic absorbing portion, another end of the nozzle movably inserted to the air supply tube; and
a driver connected to the nozzle, the driver configured to drive the nozzle and the elastic absorbing portion to move upward to press against a bottom of the FOUP when the FOUP is placed on the supporting surface, thereby causing the elastic absorbing portion to be vertically deformed to maintain an airtight connection.

8. The air purifying system of claim 7, wherein the air tight connecting unit further comprises a connecting rod connected to the nozzle, the driver is configured to drive the nozzle and the elastic absorbing portion to move upward through the connecting rod.

9. The air purifying system of claim 7, wherein the driver is an air cylinder.

10. The air purifying system of claim 7, wherein the air purifying device further comprises:
an air discharging assembly, comprises:
an air pump, wherein the air discharging assembly discharges air from the FOUP by the air pump when the air supply assembly begins to supply the purified air to the FOUP, and detects a humidity and a temperature of the discharged air, the detected humidity and the detected temperature corresponding to a relative humidity of the discharged air, when the relative humidity is equal to a preset relative humidity, the air supply assembly stops supplying the purified air to the FOUP and the air discharging assembly stops discharging air from the FOUP;
an air discharging tube connected to the air pump; and
another the said airtight connecting unit connecting the air discharging tube to the FOUP in an airtight manner.

11. The air purifying system of claim 10, wherein the air pump is a vacuum air pump.

12. The air purifying system of claim 7, wherein the elastic absorbing portion is made of rubber.
